(19) United States
(12) Patent Application Publication
(10) Pub. No.: US 2010/0091517 A1
(43) Pub. Date: Apr. 15, 2010

(54) ACTIVATED LOW-POWER LIGHTING

(75) Inventors: Stephen Brockman, Greenfield, IN (US); Steven Batti, Hillsboro, OR (US)

Correspondence Address: BAKER & DANIELS LLP, 300 NORTH MERIDIAN STREET, SUITE 2700, INDIANAPOLIS, IN, 46204, US

(73) Assignee: Mensa Technology, Noblesville, IN (US)

(21) Appl. No.: 12/572,686

(22) Filed: Oct. 2, 2009

Related U.S. Application Data
(60) Provisional application No. 61/102,454, filed on Oct. 3, 2008.

(51) Int. Cl. H01L 33/00

(52) U.S. Cl. 362/555; 362/558

(57) ABSTRACT

The present invention provides a lighting unit comprising a diffusion optic fibre, a light emitting diode (LED) coupled to the optic fibre; and an actuator connected to the LED for selectively activating the LED so that light is sent through the optic fibre and provides lighting. The lighting unit is structured and arranged for at least one of path lighting, staircase lighting, outdoor mats, mailbox lighting; curb address lights, driveway lighting, plant lighting, boat dock lighting, exterior house lighting, furniture patios, specialty home products, airplane lighting, motorcycle lighting, boat lighting; and auto lighting. The lighting unit may also be structured and arranged to be combined with at least one of a net, a ball, a glove, an out-of-bounds lighting, a bicycle, a tricycle, a big-wheels, and golf equipment. The fiber may be wound into thread and woven into at least one of clothing, coats, hats, gloves, bracelets, necklaces, running vests, backpacks, strollers, carriages, and pet collars. The lighting unit may be structured and arranged for at least one of hospital/nursing home lighting, schools and school facilities, movie theatres, industrial signage for property, buildings or vehicles, streets and highways, road signs; and fencing.

### FIELD OF THE INVENTION

The present invention relates to lighting systems and, more specifically, to lighting systems applications with low power constraints.

### BACKGROUND ART

Nitelights are well known to provide lighting to individuals at night or in dark locations. However, conventional nitelights may waste power and have ineffective properties for assisting night vision. Further improvements in such lights are desired.

### SUMMARY OF THE INVENTION

The present invention involves a lighting unit comprising: a diffusion optic fibre; a light emitting diode (LED), and an actuator. The LED is coupled to the diffusion optic fibre, and the actuator is connected to the LED for selectively activating the LED. In this manner, light may be sent through the optic fibre and provide lighting.

### BRIEF DESCRIPTION OF THE DRAWINGS:

The features of this invention, and the manner of attaining them, will become more apparent and the invention itself will be better understood by reference to the following description of embodiments of the invention taken in conjunction with the accompanying drawings.

FIGS. 1A-1C are perspective views of a lighting unit according to one embodiment of the invention.

FIGS. 2A-2D are perspective views of a lighting unit according to a second embodiment of the present invention.

FIGS. 3A-3D are perspective views of a lighting unit having suction cup mounting according to a further embodiment of the present invention.

FIGS. 4A-4D are perspective views of a lighting unit having hanging diffusers according to a further embodiment of the present invention.

FIGS. 5A-5D are perspective views of a lighting unit having a return connection according to a further embodiment of the present invention.

FIGS. 6A-6E are perspective views of a lighting unit having diffuser pens according to a further embodiment of the present invention.

FIGS. 7A-7D are perspective views of a lighting unit for book reading according to a further embodiment of the present invention.

FIGS. 8A-8B are perspective views of a lighting unit according to a further embodiment of the present invention.

FIGS. 9A-9C are perspective views of a lighting unit according to a further embodiment of the present invention.

FIGS. 10A-10D are perspective views of a lighting unit according to a further embodiment of the present invention.

FIGS. 11A-11C are perspective views of a lighting unit according to a further embodiment of the present invention.

FIGS. 12A-12C are perspective views of a lighting unit according to a further embodiment of the present invention.

FIGS. 13A-13C are perspective views of a lighting unit according to a further embodiment of the present invention.

FIGS. 14A-14D are perspective views of a lighting unit having a handle grip according to a further embodiment of the present invention.

FIGS. 15A-15D are perspective views of a lighting unit according to a further embodiment of the present invention.

Corresponding reference characters indicate corresponding parts throughout the several views. Although the drawings represent embodiments of the present invention, the drawings are not necessarily to scale and certain features may be exaggerated in order to better illustrate and explain the present invention. The exemplifications set out herein illustrate embodiments of the invention in several forms and such exemplification is not to be construed as limiting the scope of the invention in any manner.

### DETAILED DESCRIPTION OF EMBODIMENTS OF THE INVENTION

The embodiments discussed below are not intended to be exhaustive or limit the invention to the precise forms disclosed in the following detailed description. Rather, the embodiments are chosen and described so that others skilled in the art may utilize their teachings.

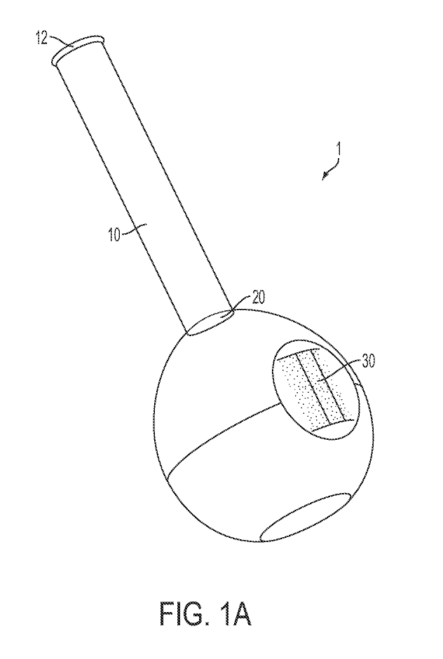

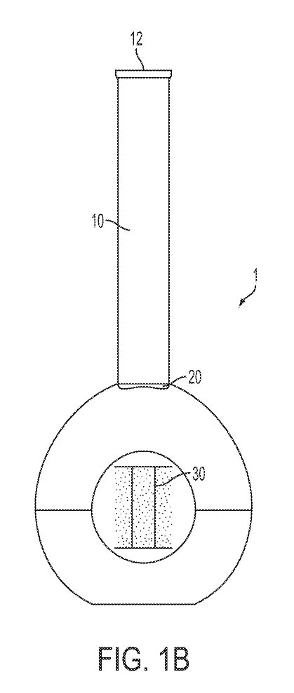

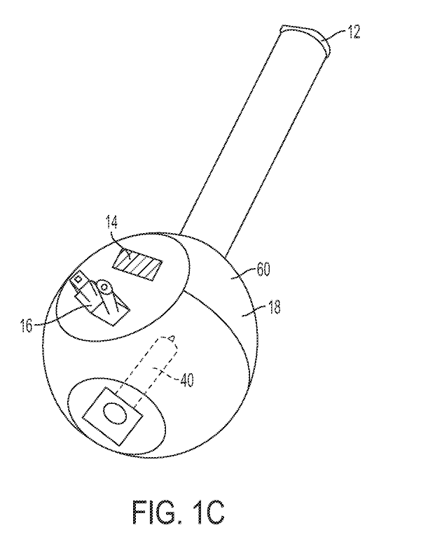

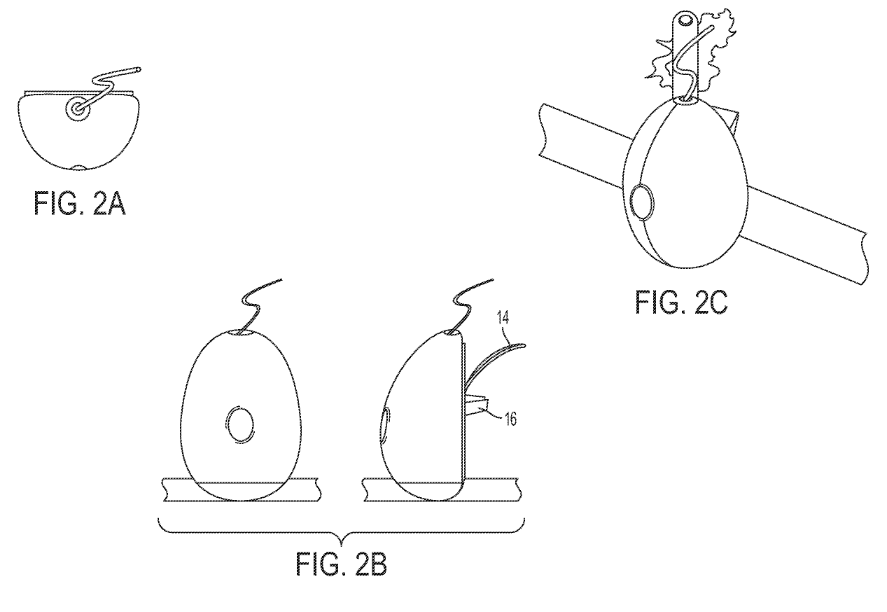

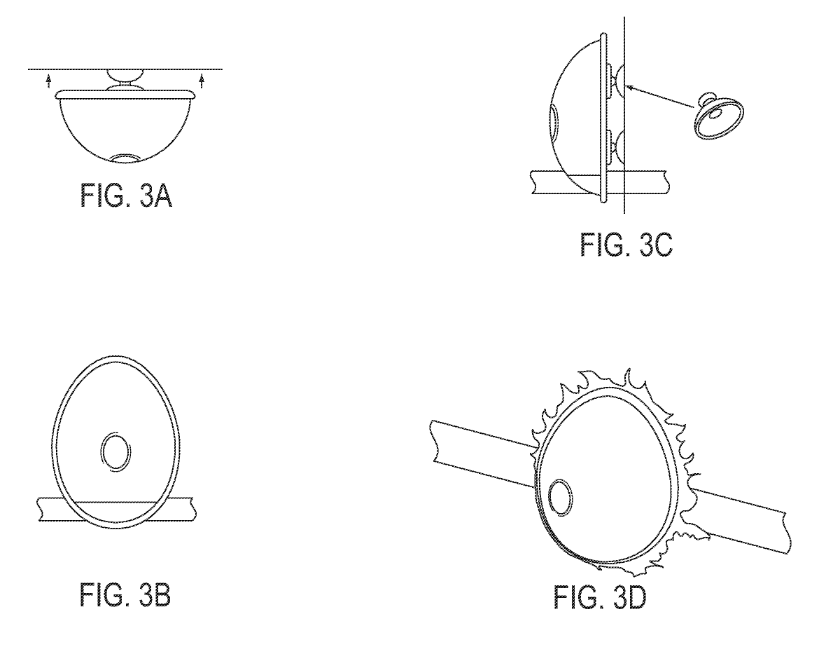

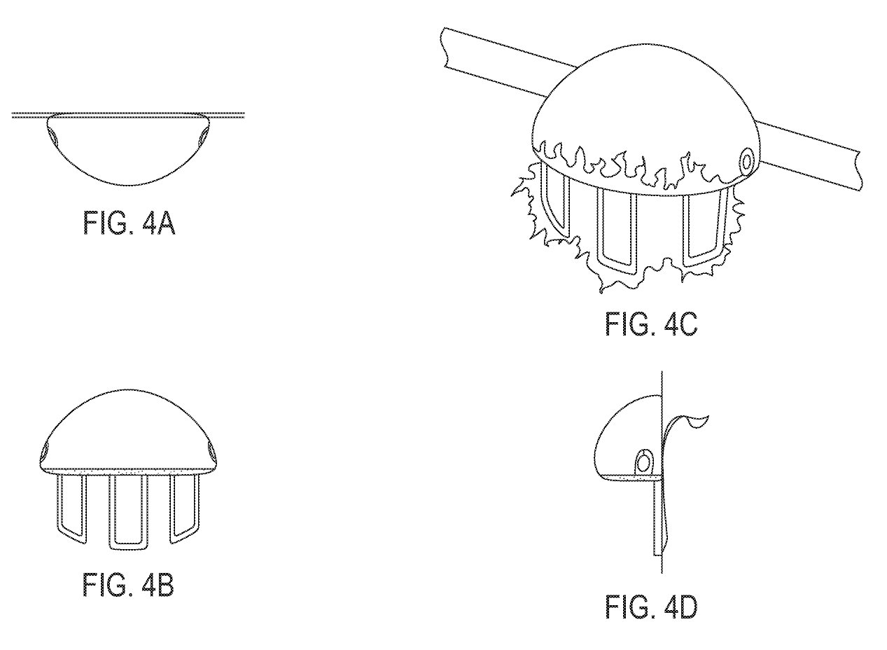

FIGS. 1A-1C illustrate lighting unit 1 according to one embodiment of the invention. Lighting unit 1 has a plurality of components including diffusion optic fibre 10 and light emitting diode (LED) 20 which is coupled to optic fibre 10. Also, actuator 30 is connected to LED 20 for selectively activating LED 20 so that light is sent through optic fibre 10 and provides lighting.

With the combination of actuator 30 for selective actuation of lighting unit 1, LED 20 for a low-power consumption light source, and optic fibre 10 for conveying and diffusing light into the environment, a great deal of light may be provided at appropriate times with efficiency. Such a device is also relatively small and light weight, allowing for disposition on walls in building or remotely on various structures. Wall mounting may be accomplished using adhesive strip 14 to adhere to a wall, or alternatively electric plugs 16 may mount lighting unit 1 into a wall electrical socket (not shown), may be mounted on a flat surface if housing 18 also has a compatible bottom, or may be attached to a wall using fasteners in a conventional manner. Lighting unit 1 may also be attached to other items such as vehicles, furniture, fences, etc. by use of adhesive strip 14. Using battery 40, the location of lighting unit 1 is not constrained by requiring coupling with line current.

In one embodiment according to the invention, lighting unit 1 is adapted to be actuated by a physical switch wherein actuator 30 includes a conventional on/off switch. In an alternative embodiment according to the invention, lighting unit 1 is adapted to be actuated by light wherein actuator 30 includes a light sensor, so that when it becomes dark the sensed lack of light causes actuator 30 to provide power to LED 20. In another embodiment, lighting unit 1 is adapted to be actuated by sound wherein actuator 30 includes an audio sensor, so that when sound is detected actuator 30 powers LED 20. In still another embodiment, lighting unit 1 is adapted to be actuated by motion wherein actuator 30 includes a motion sensor, so that when motion is sensed actuator 30 powers LED 20. In an additional embodiment, lighting unit 1 is adapted to be actuated by application of pressure wherein actuator 30 includes a pressure sensor, so that when pressure is sensed actuator 30 powers LED 20. In a further embodiment, lighting unit 1 is adapted to be actuated by a wireless signal, such as a radio signal, a WiFi signal, a cellular phone signal, etc., and thus actuator 30 includes a receiver for one or more particular types of signals. Optionally, actuator 30 may include a processor with a receiver so that lighting unit 1 may be selectively addressable, wherein a central control unit (not shown) is enabled to selectively activate actuators 30 based on an addressing scheme.

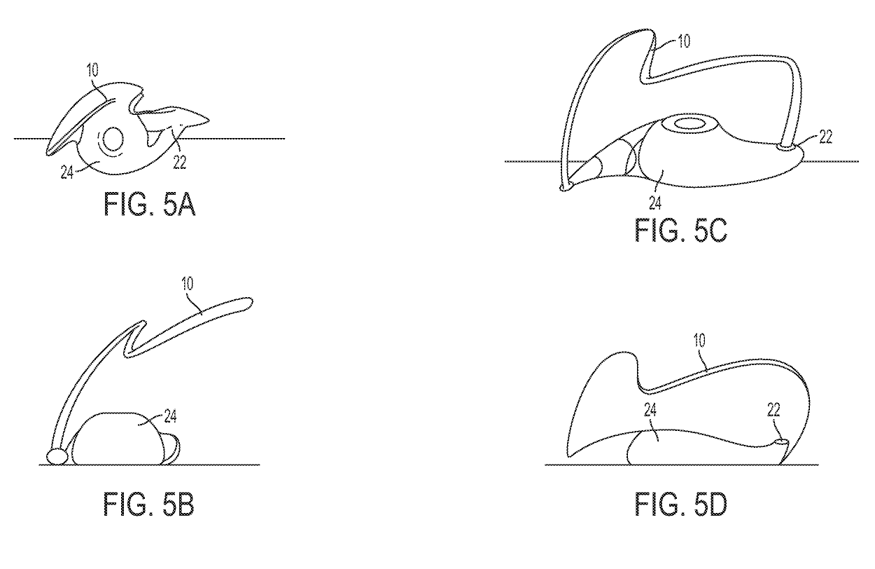

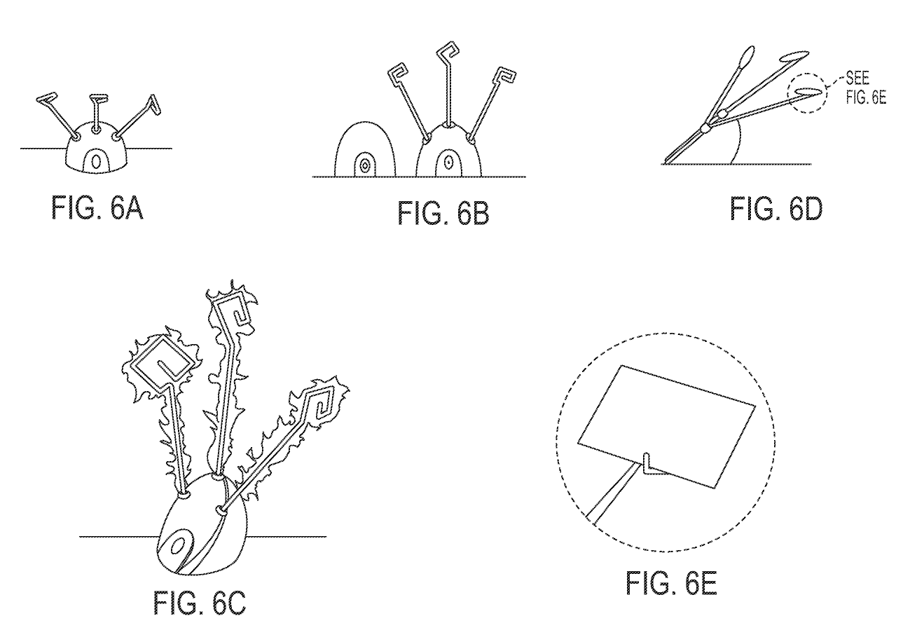

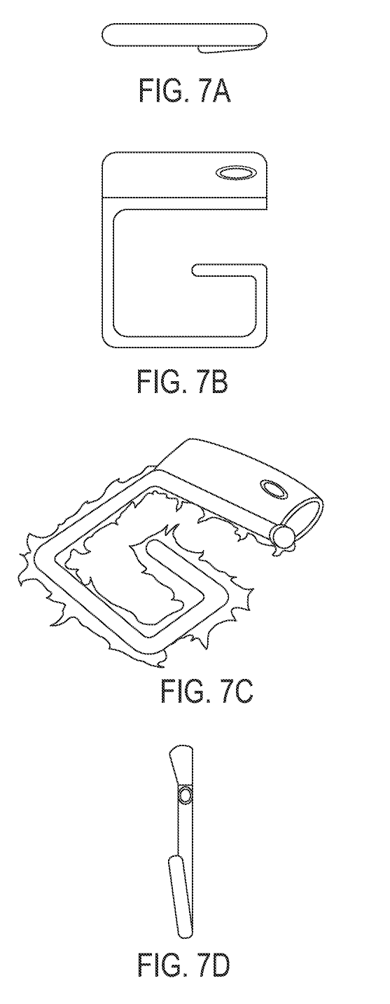

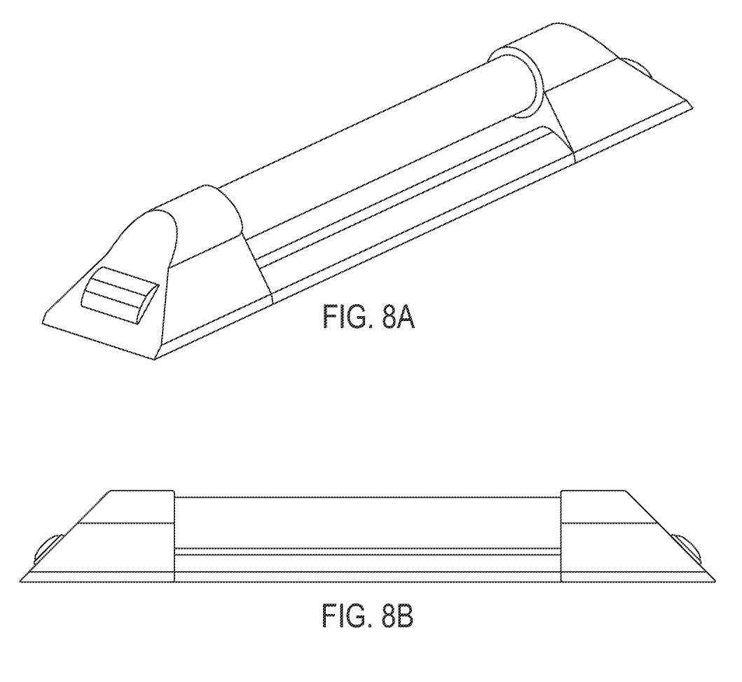

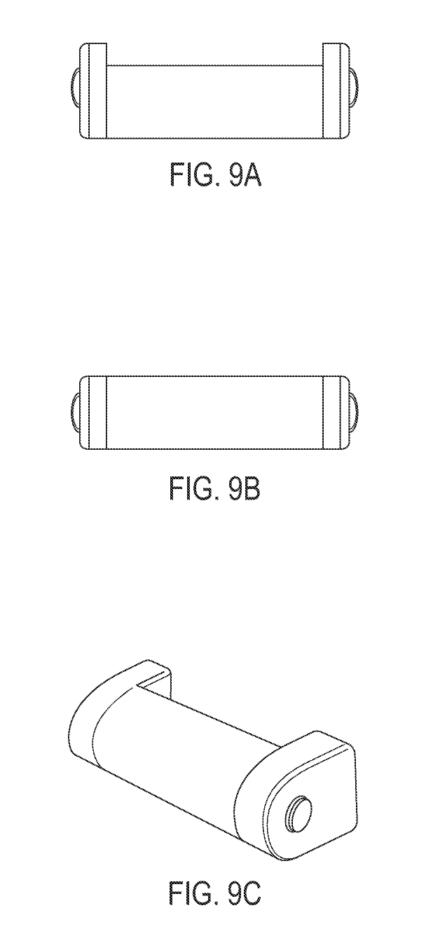

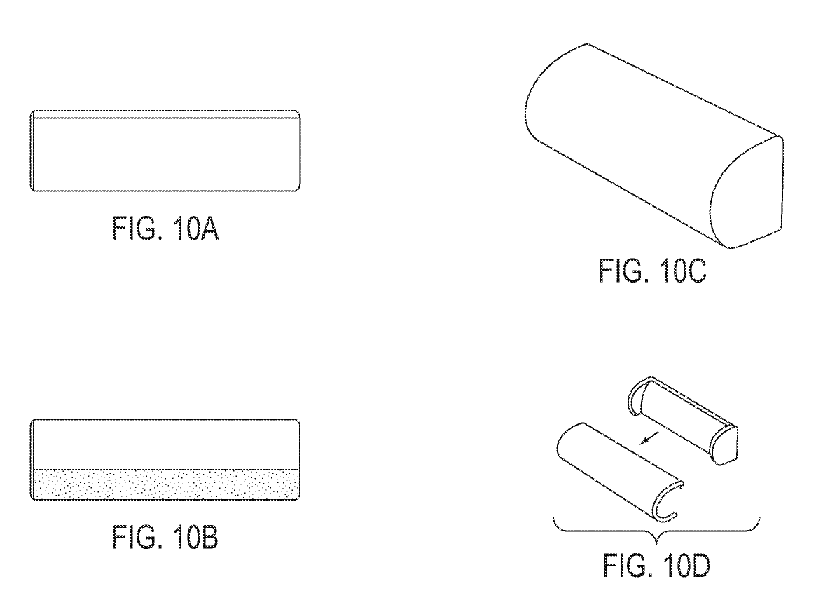

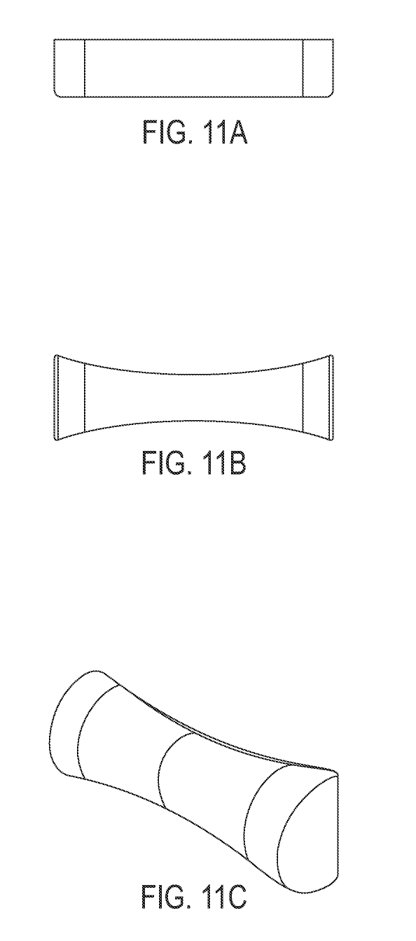

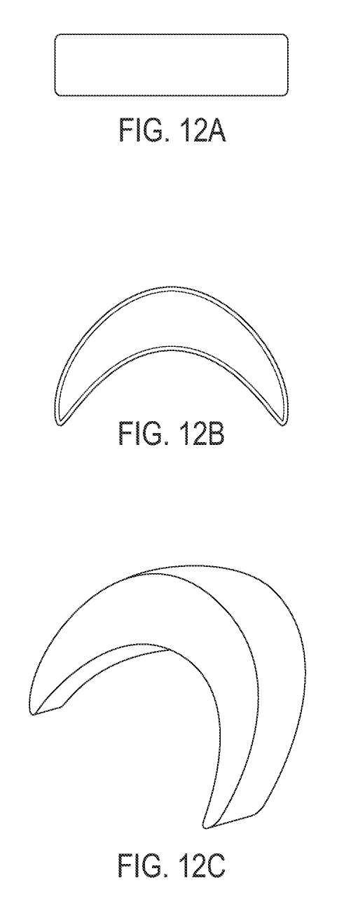

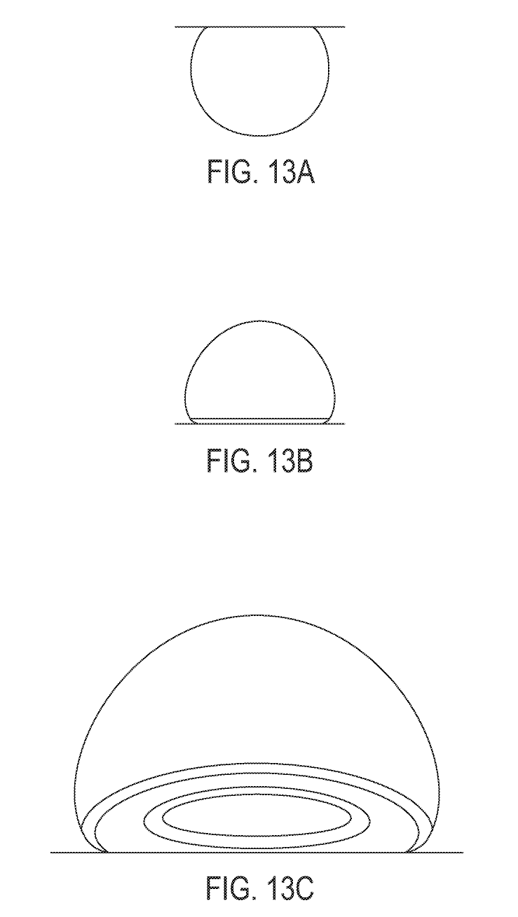

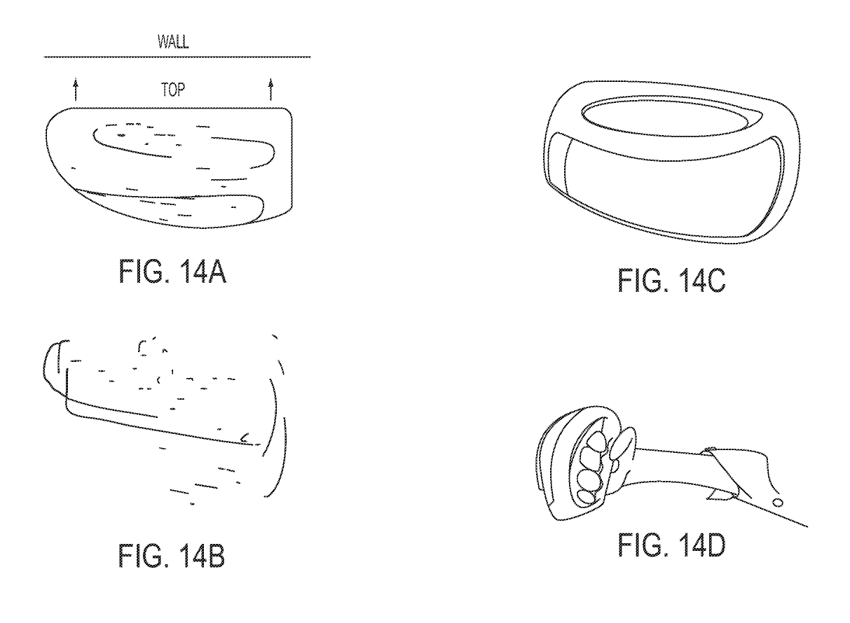

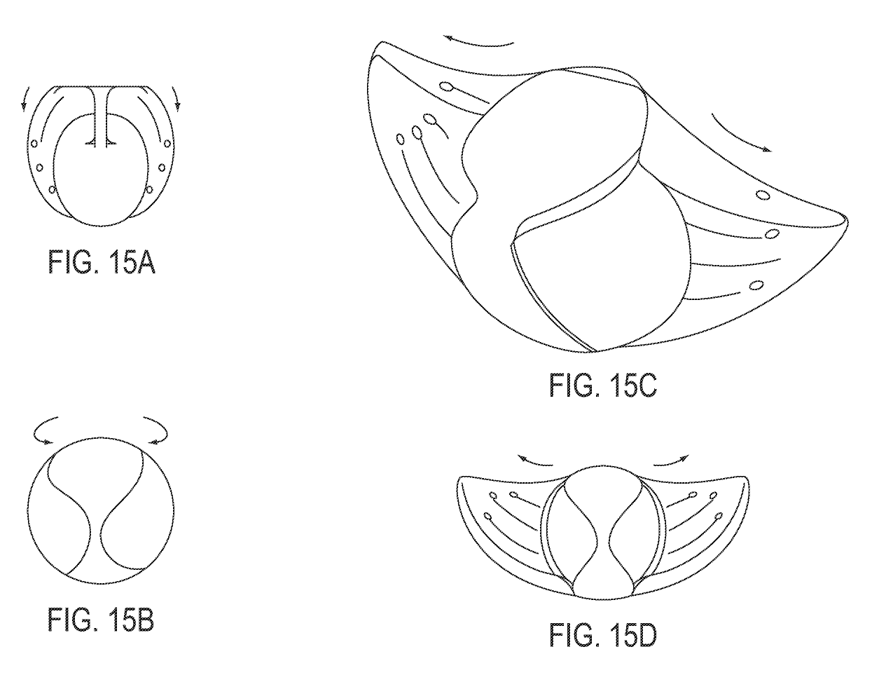

In one embodiment according to the invention, optic fibre 10 includes a light dispersive optical lightpipe. One such optical lightpipe compatible with the present invention is disclosed in U.S. Pat. No. 4,466,697, the disclosure of which is incorporated by reference herein. Optionally, optic fibre 10 may include reflective cap 12 for reflecting any light that has traversed through optic fibre 10 back through optic fibre 10 to enhance the diffusion of light from LED 20. Optionally, as shown in FIGS. 5A-5D, tip holder 22 may be included in housing 24 to provide an interference fit with an end of optic fibre 10. Tip holder 22 may optionally have a reflective surface for abutting with optic fibre 10, such that optic fibre 10 would not need reflective cap 12.

In one embodiment of the invention, LED 20 and optic fibre 10 are configured to provide a soft green colored light. For example, LED 20 may be configured to emit only soft green colored light. Alternatively, optic fibre 10 may be made of materials that filter out all but soft green colored light. For example, one such soft green colored light may be blue-green (507 nm).

Lighting unit 1 is coupled to a power source, which may be line current from an electrical system through optional electric plug 16, or alternatively may include battery 40. In the case of battery 40 supplying power to LED 20, lighting unit 1 may optionally include battery back-up unit 50 capable of providing power to LED 20 in the event that line current and/or battery 40 is incapacitated. In either configuration, lighting unit 1 may also include solar panel 60 on outer housing 18 to provide power for recharging battery 40 and/or battery back-up 50 during sun light hours.

In one embodiment according to the invention, lighting unit 1 may be designed for use as a night light. For example, a series of lighting units 1 may be configured to provide a lighting path. In this example, a first lighting unit 1 may have a pressure sensor positioned to be actuated when a person steps out of bed. The first lighting unit may further have a wireless transmitter to send a signal to additional lighting units 1 along the path from the bed to the bathroom, thereby illuminating the path to the bathroom in an otherwise dark room.

In another embodiment according to the invention, lighting unit 1 may be designed for use on road signs. For example, lighting unit 1 may have actuator 30 having both a light sensor and a motion sensor, so that optic fibre 10 may be disposed around the edges of the sign and only light up at night when a vehicle is in proximity.

In still other embodiments, lighting unit 1 may be designed for actuation for specific events with appropriate sensors in multiple environments. For Home Lighting applications, lighting unit 1 may be used for Path lighting (bar lights between rooms, or from one specific consistent location to another); Staircase lighting; Outdoor mats (Front door, other doors, decorative mats, seasonal mats—Halloween, Christmas, etc.); Mailbox lighting; Curb address lights; Driveway lighting; Plant lighting, including trees; Deck lighting; Boat dock lighting; Exterior house lighting (Roof, gutters, doors, window frames, etc.—either seasonal or continuous application); Furniture (outdoor chairs, tables, divans, etc.); Patios; and Specialty home products (lamps, rugs, wall hangings, eating utensils—glasses, etc.).

For Vehicles applications, lighting unit 1 may be configured for Airplane lighting; Motorcycle lighting; Boat lighting; and Auto lighting. In each situation, the flexibility of optic fibre 10 allows an efficient placement of illumination at locations that may otherwise be difficult to provide adequate conventional bulb or LED lighting and/or electrical connection. As vehicles are conventionally used in outdoor applications, such use of lighting unit 1 is particularly useful with battery 40 and solar panel 60.

For Sporting Applications, lighting unit 1 is useful in the construction of nets, balls, gloves, out-of-bounds lighting for such sports as volleyball, badmitten tennis, soccer, Bicycles, tricycles, big-wheels, etc.; and golf (particularly for night-time golf situations). Lighting Unit 1 provides visual clarity to those sports equipment, without significantly changing the physical dimensions of the equipment.

Other Specialty Lighting applications may utilize lighting unit 1, for example Clothing and Apparel. Using a small fibre for optic fibre 10 that is wound into thread, lighting unit 1 may be woven into clothing, lighted and potentially constantly variable/changing for coats, hats, gloves, etc. Other types of apparel include Bracelets (wrist and ankle); Necklaces; Running Vests, backpacks, etc.; Strollers & carriages; Pet collars (may be configured with circuitry causing lighting unit 1 to flash and emit sound when exiting stated boundaries).

Lighting Unit 1 is also useful in Industrial Applications such as Hospital/Nursing Home lighting (for example, lighting path example above); K-12 Schools and facilities (for example, lighting for lockers); Movie Theatres (for example, low level lighting to illuminate walking paths while not disrupting view of the film); Industrial Signage (property, buildings & vehicles); Streets &

Highways (for example, the road sign example mentioned above); Road Signs; and Fencing.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A lighting unit comprising:
a diffusion optic fibre;
a light emitting diode (LED) coupled to said optic fibre; and
an actuator connected to said LED for selectively activating said LED so that light is sent through said optic fibre and provides lighting.

2. The lighting unit of claim 1 wherein said diffusion optic fibre emits a generally green light.

3. The lighting unit of claim 1 wherein said LED emits a generally green light.

4. The lighting unit of claim 1 further comprising a battery coupled to said LED to provide power to activate said LED.

5. The lighting unit of claim 4 further comprising a battery back-up unit coupled to said battery.

6. The lighting unit of claim 1 wherein said actuator includes a light sensor.

7. The lighting unit of claim 1 wherein said actuator includes a sound sensor.

8. The lighting unit of claim 1 wherein said actuator includes a motion sensor.

9. The lighting unit of claim 1 wherein said actuator includes a switch actuable by a wireless signal.

10. The lighting unit of claim 1 structured and arranged for at least one of path lighting, staircase lighting, outdoor mats, mailbox lighting; curb address lights, driveway lighting, plant lighting, boat dock lighting, exterior house lighting, furniture patios, and specialty home products

11. The lighting unit of claim 1 structured and arranged for at least one of airplane lighting, motorcycle lighting, boat lighting; and auto lighting.

12. The lighting unit of claim 1 structured and arranged to be combined with at least one of a net, a ball, a glove, an out-of-bounds lighting, a bicycle, a tricycle, a big-wheels, and golf equipment.

13. The lighting unit of claim 1 wherein said fiber is wound into thread and woven into at least one of clothing, coats, hats, gloves, bracelets, necklaces, running vests, backpacks, strollers, carriages, and pet collars.

14. The lighting unit of claim 1 structured and arranged for at least one of hospital/nursing home lighting, schools and school facilities, movie theatres, industrial signage for property, buildings or vehicles, streets and highways, road signs; and fencing.
